(19) United States
(12) Patent Application Publication
(10) Pub. No.: US 2025/0279295 A1
(43) Pub. Date: Sep. 4, 2025

(54) Method for Determining a Picking Sequence for a Semiconductor Pick-and-Place Device

(71) Applicant: Robert Bosch GmbH, Stuttgart (DE)

(72) Inventors: Christian Eniglein, Reutlingen (DE); Marcus Stitz, Metzingen (DE); Klaus Heyers, Reutlingen (DE); Marcus Parentis, Gammertingen (DE)

(21) Appl. No.: 18/857,746

(22) PCT Filed: Apr. 13, 2023
(86) PCT No.: PCT/EP2023/059623

§ 371 Date: Oct. 17, 2024

(30) Foreign Application Priority Data
Apr. 27, 2022 (DE) 10 2022 204 077.5

(51) Int. Cl. H01L 21/67

(52) U.S. Cl. CPC H01L 21/67144; H01L 21/67271

(57) ABSTRACT

The disclosure relates to a method for determining a picking sequence for a semiconductor pick-and-place device which is designed to remove semiconductors from a store of semiconductors according to the picking sequence and to assemble them on a substrate, wherein the method comprises the following steps: for each semiconductor from the store of semiconductors, providing a value for at least one performance parameter; and determining the picking sequence on the basis of the provided values for the at least one performance parameter in such a way that a substrate can be populated optimally in respect of the at least one performance parameter on the basis of the picking sequence.

The invention relates to a method for determining a picking sequence for a semiconductor pick-and-place device and, in particular, to a method for determining a picking sequence for a semiconductor pick-and-place device such that electronic circuits assembled on the basis of the picking sequence are optimized with respect to at least one performance parameter.

In power electronic applications, the individual semiconductor chips required are often combined in so-called power modules, i.e. the semiconductor chips required are mounted on a circuit board or a substrate, e.g. a ceramic carrier, and connected to each other via conductor tracks. The assembly of the circuit board with the semiconductor chips or semiconductors is usually carried out using so-called semiconductor pick-and-place device.

Such semiconductor pick-and-place devices, which are generally also referred to as pick-and-place devices, are used to successively remove semiconductors from a processed and pre-measured wafer from a plurality of semiconductors and to place them in an orderly sequence on a carrier, e.g. a ceramic substrate carrier of a power module, a reel, a tape & reel package, a circuit board or the like, wherein the individual semiconductors mounted on the substrate are usually subsequently interconnected in parallel via conductor tracks.

In order to enable optimal and high-performance operation of power modules or such semiconductors mounted on a substrate and connected in parallel, care should be taken to ensure that semiconductors mounted one after the other on the substrate of a power module are close to each other in terms of their specifications.

A system is known from publication EP 1 480 507 B1 in which semiconductors are provided on a wafer table during assembly on a substrate, where they are picked up by a semiconductor pick-and-place device, transported and placed on the substrate, which rests on a support surface of a substrate table. The wafer table is aligned at a predetermined angle to the support surface of the substrate table, wherein the wafer table is partially positioned under the substrate table. The semiconductor pick-and-place device further comprises a carriage with a swivel arm which carries a bond head, wherein the swivel arm can be swiveled back and forth between two predetermined rotational positions, wherein in the first rotational position a longitudinal axis of the swivel arm forms the predetermined angle with the normal to the supporting surface of the substrate table, and wherein in the second rotational position the longitudinal axis of the swivel arm runs perpendicular to the supporting surface of the substrate table.

The invention is thus based on the task of providing an optimized picking sequence for a semiconductor pick-and-place device, or sequence based on which semiconductors are removed from a store of semiconductors by a semiconductor pick-and-place device and mounted on a substrate or carrier, in order to enable optimum and high-performance operation of power modules with semiconductors mounted in this way on a substrate and connected in parallel.

The problem is solved by a method for determining a picking sequence for a semiconductor pick-and-place device according to the features of claim 1.

The problem is also solved by a control device for determining a picking sequence for a semiconductor pick-and-place device according to the features of claim 7.

### DISCLOSURE OF THE INVENTION

According to one embodiment of the invention, this task is solved by a method for determining a picking sequence for a semiconductor pick-and-place device which is designed to remove semiconductors from a store of semiconductors in accordance with the picking sequence and to mount them on a substrate, wherein for each semiconductor from the store of semiconductors, a value for at least one performance parameter is provided in each case and the picking sequence is determined based on the values provided for the at least one performance parameter in such a way that a substrate can be optimally loaded based on the picking sequence with respect to the at least one performance parameter.

A performance parameter is a parameter that describes the specification of semiconductors.

Substrate is also understood to mean, in particular, a measured and processed wafer.

The fact that the substrate can be optimally populated with respect to the at least one performance parameter also means that the substrate is populated based on the respective values for the at least one performance parameter of the individual semiconductors from the store of semiconductors in such a way that the final module or the module ultimately populated by the semiconductor pick-and-place device has the maximum possible performance with respect to the desired application.

The fact that the substrate is assembled on the basis of the respective values for the at least one performance parameter of the individual semiconductors from the store of semiconductors in such a way that the module finally or ultimately assembled by the semiconductor pick-and-place device has the maximum possible performance with regard to the desired application has the advantage that costs can be saved. For example, there are fewer errors in the subsequent application of the assembled substrate. In addition, the number of semiconductors required for certain applications or desired power modules can be reduced by a correspondingly optimized selection of semiconductors, which in turn results in smaller power modules. This also avoids the need for time-consuming classification of semiconductors during production. Overall, this provides an optimized picking sequence for a semiconductor pick-and-place device, which enables optimal and high-performance operation of power modules or such semiconductors mounted on a substrate and connected in parallel.

For each semiconductor from the store of semiconductors, the method may further comprise measuring or detecting the corresponding value for the at least one performance parameter.

The fact that the individual values are measured, means in particular that they are recorded based on corresponding sensors. A sensor, which is also referred to as a detector or (measuring) probe, is a technical component that can acquire certain physical or chemical properties and/or the material characteristics of its surroundings qualitatively, or quantitatively as a measured variable.

Consequently, circumstances outside the actual data processing system on which the picking sequence is determined can be taken into account and incorporated into the method. Furthermore, although additional costs may be incurred due to the corresponding classification or labeling of the individual semiconductors, these are compensated many times over by the optimized picking sequence.

In one embodiment, the step of determining the picking sequence based on the provided values for the at least one performance parameter comprises determining the picking sequence based on the provided values for the at least one performance parameter and potential travel times of the semiconductor pick-and-place device.

Traversing times of the semiconductor pick-and-place device are understood to be the times required to bring the semiconductor pick-and-place device or a corresponding arm of the semiconductor pick-and-place device into the position required to pick up or receive a corresponding or desired semiconductor.

On the one hand, this allows the final assembled substrate or final power module to be optimized in terms of its performance and costs, wherein at the same time the processing times of the semiconductor pick-and-place device required to assemble the substrate and thus also the total time required to assemble the corresponding substrate can be minimized.

The method for determining the picking sequence is designed in such a way that it minimizes the fluctuations of at least one performance parameter on the substrates, for example by calculating the mean value of the performance parameter of different batches and adjusting the distribution of the components in such a way that at the end of a picking process of a wafer, a chip is positioned as close as possible to the mean value of the batches.

Arrangement of the chips in the reel in a linear or sinusoidal distribution starting and ending with a value close to the mean value of at least one performance parameter determined over several batches.

In addition, the step of determining the picking sequence based on the values provided for the at least one performance parameter may comprise determining the picking sequence based on a machine learning algorithm.

Machine learning algorithms are based on using statistical methods to train a data processing system so that it can perform a specific task without having been explicitly programmed to do so. The goal of machine learning is to construct algorithms that can learn and make predictions from data.

Machine learning algorithms have the advantage that comparatively accurate predictions can be made with comparatively few resources and comparatively little computing effort, which proves to be particularly advantageous if more than one performance parameter is to be taken into account or the picking sequence is to be optimized based on more than one performance parameter.

The at least one performance parameter can also be a threshold voltage.

The threshold voltage, which is also referred to as the cut-in, forward or knee voltage, indicates the voltage that must be applied to a junction of a rectifier or diode so that the current becomes noticeably greater than the reverse current, or the voltage from which a semiconductor diode becomes conductive in the forward direction.

Based on the threshold voltage, conclusions can thus be drawn as to whether semiconductors arranged one after the other on a substrate match each other.

However, the fact that the performance parameter is a threshold voltage, a switch-on resistance or a breakdown voltage is only one possible embodiment. For example, the at least one performance parameter can also be a breakdown voltage or a combination of several performance parameters.

With a further embodiment of the invention, a method for mounting a substrate with semiconductors by a semiconductor pick-and-place device, which is designed to remove semiconductors from a store of semiconductors according to the picking sequence and to mount a substrate with the removed semiconductors, is also disclosed, wherein the method comprises determining the picking sequence by a method described above for determining a picking sequence for a semiconductor pick-and-place device and mounting a substrate by the semiconductor pick-and-place device based on the determined picking sequence.

Thus, a method for mounting a substrate with semiconductors by a semiconductor pick-and-place device, which is based on an optimized picking sequence and in particular a picking sequence, which enables an optimal and high-performance operation of power modules or such semiconductors mounted on a substrate and connected in parallel. The fact that the substrate is assembled based on the respective values for the at least one performance parameter of the individual semiconductors from the store of semiconductors in such a way that the substrate finally or ultimately assembled by the semiconductor pick-and-place device has the maximum possible performance with regard to the desired application has the advantage that costs can be saved. For example, there are fewer errors in the subsequent application of the assembled substrate. In addition, the number of semiconductors required for certain applications or desired power modules can be reduced by a correspondingly optimized selection of semiconductors, which in turn results in smaller power modules. Furthermore, time-consuming classification of semiconductors in production can also be avoided.

With a further embodiment of the invention, a control device for determining a picking sequence for a semiconductor pick-and-place device, which is designed to remove semiconductors from a store of semiconductors according to the picking sequence and to mount them on a substrate, is also specified, wherein the control device is a provision unit, which is designed to provide a value for at least one performance parameter for each semiconductor from the store of semiconductors, and a determination unit, which is designed to determine the picking sequence based on the provided values for the at least one performance parameter in such a way that a substrate based on the picking sequence with regard to which at least one performance parameter can be optimally populated.

Thus, a control device for determining an optimized picking sequence and, in particular, a picking sequence that enables optimal and high-performance operation of power modules or semiconductors mounted on a substrate and connected in parallel in this way is provided. The fact that the substrate is assembled based on the respective values for the at least one performance parameter of the individual semiconductors from the store of semiconductors in such a way that the substrate finally or ultimately assembled by the semiconductor pick-and-place device has the maximum possible performance with regard to the desired application has the advantage that costs can be saved. For example, there are fewer errors in the subsequent application of the assembled substrate. In addition, the number of semiconductors required for certain applications or desired power modules can be reduced by a correspondingly optimized selection of semiconductors, which in turn results in smaller power modules. Furthermore, time-consuming classification of semiconductors in production can also be avoided.

The control device can also have a detection unit which is designed to measure or detect the value for the at least one performance parameter for each semiconductor from the store of semiconductors. Consequently, circumstances outside the actual data processing system on which the picking sequence is determined can be taken into account and incorporated into the method. Furthermore, although additional costs may be incurred due to the corresponding classification or labeling of the individual semiconductors, these are compensated many times over by the optimized picking sequence.

In one embodiment, the determination unit is further designed to determine the picking sequence based on the values provided for the at least one performance parameter and potential or corresponding travel times of the semiconductor pick-and-place device. On the one hand, this allows the final assembled substrate or final power module to be optimized in terms of its performance and costs, wherein at the same time the processing times of the semiconductor pick-and-place device required to assemble the substrate and thus also the total time required to assemble the corresponding substrate can be minimized.

In addition, the determination unit can also be designed to determine the picking sequence based on a machine learning algorithm. Machine learning algorithms have the advantage that comparatively accurate predictions can be made with comparatively few resources and comparatively little computing effort, which proves to be particularly advantageous if more than one performance parameter is to be taken into account or the picking sequence is to be optimized based on more than one performance parameter.

The at least one performance parameter can also be a threshold voltage. Based on the threshold voltage, conclusions can be drawn as to whether semiconductors arranged one after the other on a substrate match each other.

However, the fact that the performance parameter is a threshold voltage is only one possible embodiment. For example, the at least one performance parameter can also be a breakdown voltage or a combination of several performance parameters.

With a further embodiment of the invention, a semiconductor pick-and-place device is also specified, which is designed to remove semiconductors from a store of semiconductors according to the picking sequence and to mount them on a substrate, wherein the semiconductor pick-and-place device is designed as a receiving unit, to receive a picking sequence determined by a control device described above for determining a picking sequence for a semiconductor pick-and-place device, and wherein the semiconductor pick-and-place device is designed to assemble a substrate based on the received picking sequence.

Thus, a semiconductor pick-and-place device for mounting a substrate with semiconductors based on an optimized picking sequence and, in particular, a picking sequence which enables optimum and high-performance operation of power modules or semiconductors mounted on a substrate and connected in parallel in this way is disclosed. The fact that the substrate is assembled based on the respective values for the at least one performance parameter of the individual semiconductors from the store of semiconductors in such a way that the substrate finally or ultimately assembled by the semiconductor pick-and-place device has the maximum possible performance with regard to the desired application has the advantage that costs can be saved. For example, there are fewer errors in the subsequent application of the assembled substrate. In addition, the number of semiconductors required for certain applications or desired power modules can be reduced by a correspondingly optimized selection of semiconductors, which in turn results in smaller power modules. Furthermore, time-consuming classification of semiconductors in production can also be avoided.

In summary, the present invention provides a method for determining a picking sequence for a semiconductor pick-and-place device such that, based on the picking sequence, populated substrates or power modules are optimized with respect to at least one performance parameter.

The described embodiments and developments can be combined with one another as desired.

Further possible configurations, developments and implementations of the invention also comprise not explicitly mentioned combinations of features of the invention described above or below with respect to exemplary embodiments.

### BRIEF DESCRIPTION OF THE DRAWINGS

The accompanying drawings are intended to provide a better understanding of the embodiments of the invention. They illustrate embodiments and, in connection with the description, serve to explain principles and concepts of the invention.

Other embodiments and many of the mentioned advantages become apparent from the drawings. The illustrated elements of the drawings are not necessarily shown to scale with respect to one another.

Shown are:

FIG. 1. shows a flowchart of a method for mounting semiconductors on a substrate by a semiconductor pick-and-place device, according to embodiments of the invention;

FIG. 2. shows a schematic block diagram of a control device for determining a picking sequence for a semiconductor pick-and-place device according to embodiments of the invention.

In the figures of the drawings, identical reference signs denote identical or functionally identical elements, parts or components, unless stated otherwise.

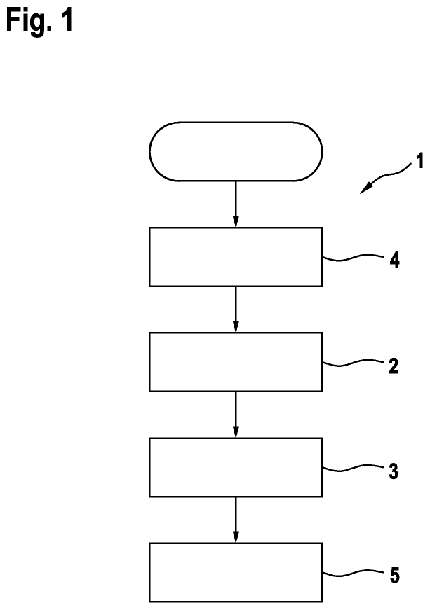

FIG. 1 shows a flowchart of a method for mounting semiconductors on a substrate by a semiconductor pick-and-place device 1 according to embodiments of the invention.

Semiconductor pick-and-place device, which are generally also referred to as pick-and-place devices, are used to successively remove semiconductors from a store of semiconductors, i.e. a large number of semiconductors or from numerous, similar semiconductors of a measured and processed wafer, which are usually located next to each other on a carrier, and to mount them successively on a substrate or a circuit board, wherein the individual semiconductors mounted on the substrate are usually then connected in parallel and connected to each other via conductor tracks.

In order to enable optimum and high-performance operation of power modules or such semiconductors mounted on a substrate and connected in parallel, care should be taken to ensure that semiconductors mounted one after the other on the substrate of a power module and the individual modules are close to each other in terms of their specification or performance.

Furthermore, the maximum number of semiconductors required for an application or to be placed on such a substrate depends not only on the required minimum distances and the respective sizes, but also strongly on the desired maximum performance or the maximum performance required.

Modules with asymmetries can also lead to component ageing, a deterioration in performance or properties and even the destruction of the entire module.

To enable optimized performance, care should therefore be taken to ensure that the individual substrates mounted one after the other on a substrate do not differ too greatly from one another in terms of at least one performance parameter.

FIG. 1 shows a method in which, in a step 2, a value for at least one performance parameter is provided for each semiconductor from a store of semiconductors and, in a subsequent step 3, a picking sequence is determined on the basis of the values provided for the at least one performance parameter in such a way that a substrate can be optimally loaded with respect to the at least one performance parameter on the basis of the picking sequence determined.

The fact that the substrate is assembled based on the respective values for the at least one performance parameter of the individual semiconductors from the store of semiconductors in such a way that the substrate finally or ultimately assembled by the semiconductor pick-and-place device has the maximum possible performance with regard to the desired application has the advantage that costs can be saved. For example, there are fewer errors in the subsequent application of the assembled substrate. In addition, the number of semiconductors required for certain applications or desired power modules can be reduced by a correspondingly optimized selection of semiconductors, which in turn results in smaller power modules. This also avoids the need for time-consuming classification of semiconductors during production. Furthermore, time-consuming classification of semiconductors in production can also be avoided. Overall, this provides an optimized picking sequence for a semiconductor pick-and-place device, which enables optimal and high-performance operation of power modules or such semiconductors mounted on a substrate and connected in parallel.

Based on a picking sequence determined in this way, it can be ensured that there are only minor, in particular negligible, differences between two semiconductors or two assembled substrates mounted in immediate succession with regard to at least one performance parameter. Based on the picking sequence determined, it is also possible to subsequently assemble identical power modules or power modules with slight, tolerable differences.

The picking sequence can begin and/or end with ascending or descending values for at least one performance parameter. In particular, the picking sequence can also be determined in such a way that a certain desired shape results with regard to the sequence of values of the successively mounted semiconductors for the at least one performance parameter, for example a parabolic, sinusoidal or sawtooth-shaped curve.

Furthermore, the determined picking sequence can then be made available, in particular in the form of a data file, for example a text file.

As FIG. 1 further shows, the method 1 further comprises a step 4 of respectively detecting the value for the at least one performance parameter for each semiconductor from the store of semiconductors. In particular, the semiconductors can be divided into classes or semiconductors with the same values for at least one performance parameter can be identified. The individual values can be recorded using wafer measurements, KGD (known good die) measurements or similar methods, for example.

Further optimization can also be achieved by preselecting the corresponding or originally provided batches and wafers.

According to the embodiments of FIG. 1, the step 3 of determining the picking sequence based on the provided values for the at least one performance parameter further comprises determining the picking sequence based on the provided values for the at least one performance parameter and potential travel times of the semiconductor pick-and-place device.

The individual processing times or corresponding travel paths of the semiconductor pick-and-place device, in particular corresponding sizes of individual quantities of possible travel paths, can be taken into account, for example, based on tolerance classes for the values of the at least one performance parameter. In particular, the larger the tolerance range, the more semiconductors are usually available for selection.

In addition, step 3 of determining the picking sequence based on the values provided for the at least one performance parameter according to the embodiments of FIG. 1 comprises determining the picking sequence based on a machine learning algorithm. The machine learning algorithm, for example a neural network, may have been trained on data known from other batches, for example, with regard to the picking sequence and corresponding values for the values of the at least one performance parameter and the performance of the corresponding finally loaded or ultimately resulting substrate and, in particular, assignments between these values.

The at least one performance parameter is also a threshold voltage.

The threshold voltage describes, for example, the switching threshold of a MOSFET, wherein time differences caused by different switching thresholds of successively mounted semiconductors are undesirable, as this can lead to different loads on the individual semiconductors, especially when the corresponding module is switched on or off.

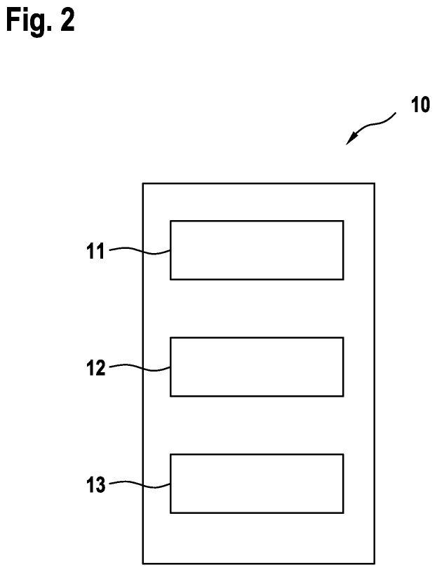

FIG. 2 shows a schematic block diagram of a control device for determining a picking sequence for a semiconductor pick-and-place device 10 according to embodiments of the invention.

As FIG. 2 shows, the control device 10 has a provision unit 11, which is designed to provide a value for at least one performance parameter for each semiconductor from the store of semiconductors, and a determination unit 12, which is designed to determine the picking sequence based on the values provided for the at least one performance parameter in such a way that a substrate can be optimally loaded based on the picking sequence with regard to the at least one performance parameter.

The provision unit can be a receiver, for example, which is designed to receive the corresponding values from a detection unit or one or more sensors. The ascertainment unit can furthermore be implemented on the basis of a code, for example, which is stored in a memory and can be executed by a processor.

According to the embodiments of FIG. 2, the control device 10 also has a detection unit 13, which is designed to detect the value for the at least one performance parameter for each semiconductor from the store of semiconductors.

The detection unit can be realized based on corresponding sensors, for example.

Furthermore, the determination unit 12 shown is designed to determine the picking sequence based on the values provided for the at least one performance parameter and potential or corresponding travel times of the semiconductor pick-and-place device.

In addition, the determination unit 12 shown is designed to determine the picking sequence based on a machine learning algorithm.

According to the embodiments of FIG. 2, the at least one performance parameter is again a threshold voltage.

1. A method for determining a picking sequence for a semiconductor pick-and-place device which is designed to remove semiconductors from a store of semiconductors in accordance with the picking sequence and to mount them on a substrate, wherein the method comprises:
providing, for each semiconductor from the store of semiconductors, a value for at least one performance parameter; and
determining the picking sequence based on the provided values for the at least one performance parameter such that a substrate is optimally loaded based on the picking sequence with respect to the at least one performance parameter.

2. The method according to claim 1, wherein the method further comprises:
recording, for each semiconductor from the store of semiconductors, the corresponding value for the at least one performance parameter.

3. The method according to claim 1, wherein the step of determining the picking sequence based on the provided values for the at least one performance parameter comprises determining the picking sequence based on the provided values for the at least one performance parameter and potential travel times of the semiconductor pick-and-place device.

4. The method according to claim 1, wherein the determining the picking sequence based on the provided values for the at least one performance parameter comprises determining the picking sequence based on a machine learning algorithm.

5. The method according to claim 1, wherein the at least one performance parameter is a threshold voltage, a switch-on resistance or a breakdown voltage.

6. A method of mounting semiconductors on a substrate by a semiconductor pick-and-place device which is adapted to pick semiconductors from a store of semiconductors according to a picking sequence and to mount them on the substrate, comprising:
determining the picking sequence by a method for determining a picking sequence for a semiconductor pick-and-place device according to claim 1; and
mounting of a substrate by the semiconductor pick-and-place device based on the determined picking sequence.

7. A control device for determining a picking sequence for a semiconductor pick-and-place device which is designed to remove semiconductors from a store of semiconductors in accordance with the picking sequence and to mount them on a substrate, the control device comprising:
a provision unit which is designed to provide a value for at least one performance parameter for each semiconductor from the store of semiconductors; and
a determination unit which is designed to determine the picking sequence based on the values provided for the at least one performance parameter such that the substrate is optimally populated based on the picking sequence with regard to the at least one performance parameter.

8. The control device according to claim 7, wherein the control device further comprises a detection unit which is designed to detect the corresponding value for the at least one performance parameter for each semiconductor from the store of semiconductors.

9. The control device according to claim 7, wherein the determination unit is designed to determine the picking sequence based on the provided values for the at least one performance parameter and potential travel times of the semiconductor pick-and-place device.

10. The control device according to claim 7, wherein the determination unit is configured to determine the picking sequence based on a machine learning algorithm.

11. The control device according to claim 7, wherein the at least one performance parameter is a threshold voltage.

12. A semiconductor pick-and-place device which is adapted to pick the semiconductors from the store of semiconductors according to the picking sequence and mount them on the substrate, wherein:
the semiconductor pick-and-place device is adapted to receive a receiving unit for receiving the picking sequence determined by the control device according to claim 7; and
the semiconductor pick-and-place device is adapted to mount the substrate based on the received picking sequence.
